(19) United States
(12) Patent Application Publication
(10) Pub. No.: US 2010/0252876 A1
(43) Pub. Date: Oct. 7, 2010

(54) Structure and method for forming an oscillating MOS transistor and nonvolatile memory

(76) Inventor: James Pan, West Jordan, UT (US)

Correspondence Address: James Pan, 655 Baker St., Apt. J210, Costa Mesa, CA, 92626, US

(21) Appl. No.: 12/418,997

(22) Filed: Apr. 6, 2009

(51) Int. Cl. H01L 29/792; H01L 21/336

(52) U.S. Cl. 257/324; 438/287; 257/E29.309; 257/E21.423

(57) ABSTRACT

With simply applying the gate voltage, the transistor will start sending out oscillating signals, working like a semiconductor “engine”. A special MOS field effect transistor (FET) includes an extended lightly doped drain and an intrinsic undoped or very lightly doped “gap” between the gate and the heavily doped source. The gap needs to be specially engineered so that the transistor is not always turned on by the MOSFET gate voltage, but will be turned on by the carriers from the forward-biased channel-drain junction diode. Oscillation occurs to the drain current (or voltage) when a suitable gate voltage is applied, due to the repeated back and forth actions of deep depletion in the transistor well and forward bias of the drain-well p-n junction diode. By forming a second spacer gate on one side of the main gate, the device can be used as a non-volatile memory, with the charges stored at the dielectrics / silicon interface, which can significantly impact the oscillating for the READ operation of a memory. This device can also be a frequency amplifier.

### BRIEF SUMMARY OF THE INVENTION

When a voltage larger than the threshold voltage is applied to the gate electrode, the transistor does not turn on like other regular MOSFETs, due to the presence of the specially engineered “gap” between source and channel.

The potential of the silicon channel follows the gate potential, causing forward biasing of the drain-channel junction diode. When the p-n junction diode is forward biased, current flows through the diode, sending carriers to the transistor channel. This is defined as “type 1” oscillation. When the p-n junction remains reversed biased, the current comes from the thermal generation or avalanche breakdown in the depleted p-n junction (channel-drain diode). The current is also called “gate controlled diode current”. This is defined as “type 2” oscillation. The amplitude of type 1 oscillation is larger then the type 2 oscillation.

When carriers are sent to the channel by the p-n junction diode in forward or reverse bias, these carriers turn on the MOS transistor. When the MOSFET is on, the inversion charges bridge the “gap” and the carriers are sent to the source.

After the MOSFET is turned on, the channel potential drops because the gate is screened by the inversion charges. This causes the p-n junction diode to be reverse biased. The current is stopped and no more carriers are sent to the transistor channel by the p-n junction diode. So the MOSFET is turned off—that brings the channel potential to again follow the gate potential, and that forward biases the p-n junction. The cycle thus repeats. The drain and the gap are engineered to control the oscillating frequency and efficiency. The gap can be constructed as a quantum well, or adjusted bandgap energy to form an intrinsic electric field, so the electrons (MOSFET) or holes (PMOSFET) can flow into the gap from the drain more easily. The drain can also have bandgap engineering or graded doping concentration, so that the p-n junction diode is responding (forward or reverse biased) to the channel potential modulated by the gate voltage.

When a second spacer gate is implemented (on one side of the main gate), the device becomes a nonvolatile memory. The WRITE operation is to apply a voltage to the 2^{nd} spacer gate to have the inversion charges trapped at the special dielectrics and the silicon interface under the 2^{nd} gate. The READ operation is to sense the output drain oscillating signal, which is affected by the interfacial charges under the 2^{nd} gate. The ERASE operation is to apply a gate voltage (opposite to the WRITE bias) to remove the trapped inversion charges.

### FIGURE CAPTIONS

FIG. 1 is a cross-section view of an oscillating MOSFET (“O-MOSFET”)

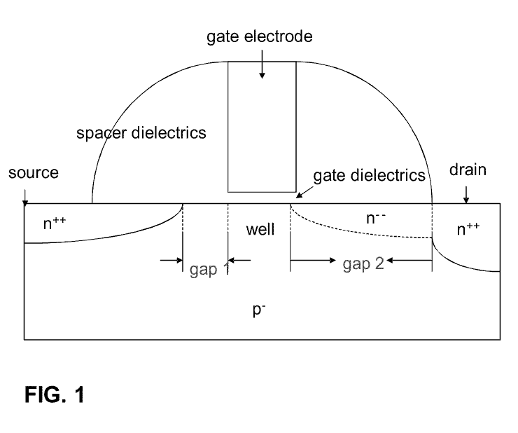

FIG. 2 illustrates how the O-MOSFET starts to oscillate - when the gate bias (VG) is applied to the gate, changing the surface potential in the well (OS), and forward-bias the well-drain p-n junction diode.

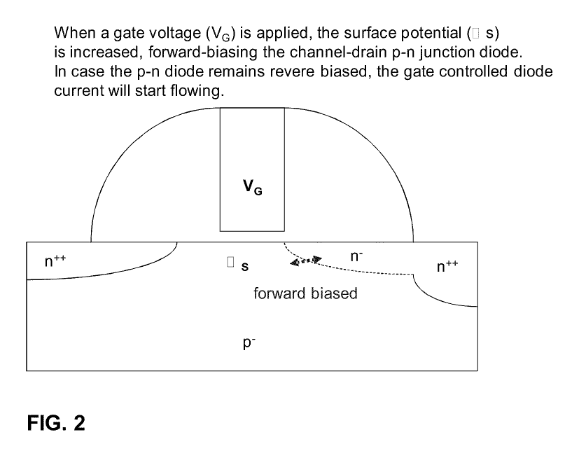

FIG. 3 shows the forward biased p-n diode sends electrons into the O-MOSFET channel. In case the p-n junction is revere biased, the gate controlled diode current starts flowing in the opposite direction.

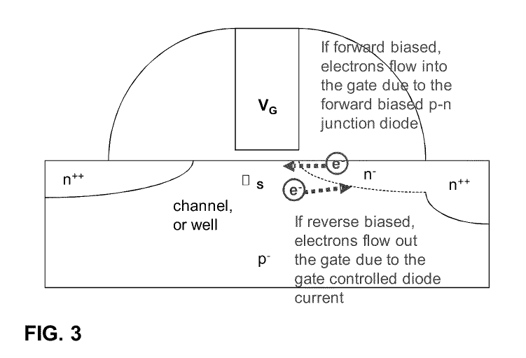

FIG. 4 shows when all the electrons are sent to the source, the transistor is off, and the channel and surface potential increases to forward bias the channel (or well)—drain p-n diode. This causes the electrons to start flowing into the channel again.

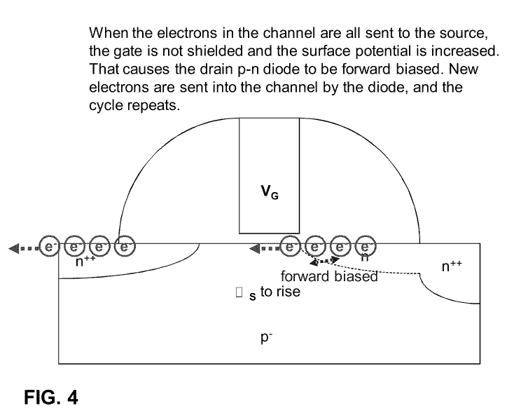

FIG. 5 shows one method to from the “gap”—by tilted implant.

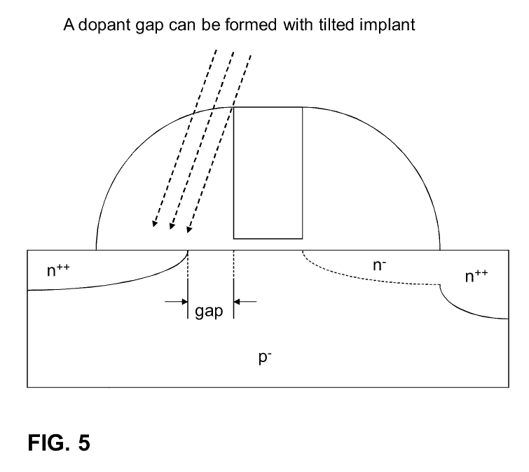

FIG. 6 shows a 2^{nd} gate is added with 2^{nd} special dielectrics to form a non-volatile device.

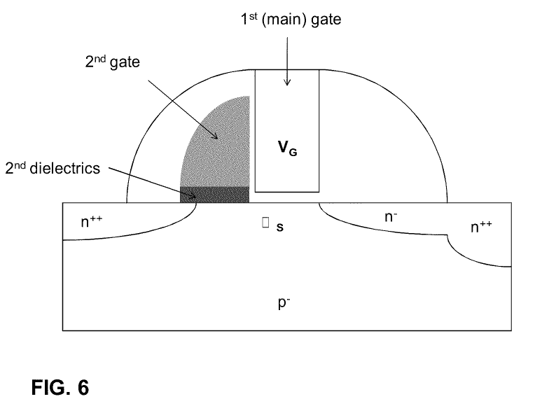

1. A carefully engineered lightly doped “gap” region is located in between the MOSFET channel under the gate and the heavily doped source. The drain is composed of a lightly doped region and a heavily doped region. Drain current and voltage oscillations happen when a gate voltage is applied. A second “spacer gate” is added with special second gate dielectrics to form a non-volatile memory. The charges are stored in the interface between silicon and the 2^{nd} dielectrics. Frequency amplification happens between the gate signal and the drain signal. The MOS transistor can be a planar or a vertical device.
